(19) United States
(12) Patent Application Publication
(10) Pub. No.: US 2014/0070074 A1
(43) Pub. Date: Mar. 13, 2014

(54) SEMICONDUCTOR INTEGRATED CIRCUIT AND IMAGE SENSOR

(71) Applicant: KABUSHIKI KAISHA TOSHIBA, Tokyo (JP)

(72) Inventors: Fumihiko TACHIBANA, Yokohama-Shi (JP); Jun DEGUCHI, Kawasaki-Shi (JP)

(73) Assignee: KABUSHIKI KAISHA TOSHIBA, Tokyo (JP)

(21) Appl. No.: 13/780,700

(22) Filed: Feb. 28, 2013

(30) Foreign Application Priority Data
Sep. 10, 2012 (JP) 2012-198671

(51) Int. Cl. H01L 27/146; G01J 1/44

(52) U.S. Cl. CPC H01L 27/14601; G01J 1/44
USPC 250/208.1; 250/206

(57) ABSTRACT

According to one embodiment, a semiconductor integrated circuit includes: a CDS (Correlated Double Sampling) circuit; and an adjustment voltage generator. The CDS circuit has a first capacitor and a second capacitor. The first capacitor has a first electrode and a second electrode. The second capacitor has a third electrode and a fourth electrode. The CDS circuit is configured to hold a voltage corresponding to light intensity as a signal voltage. The adjustment voltage generator is configured to supply an adjustment voltage to the CDS circuit. A first signal voltage is supplied to the first electrode, and a second signal voltage is supplied to the third electrode. The second electrode and the fourth electrode are commonly connected and supplied with the adjustment voltage from the adjustment voltage generator.

### CROSS REFERENCE TO RELATED APPLICATIONS

This application is based upon and claims the benefit of priority from the prior Japanese Patent Application No. 2012-198671, filed on Sep. 10, 2012, the entire contents of which are incorporated herein by reference.

### FIELD

Embodiments described herein relate generally to a semiconductor integrated circuit and an image sensor.

### BACKGROUND

A voltage value read from a pixel of an image sensor is sampled and held by a CDS (Correlated Double Sampling) circuit and amplified by a PGA (Programmable Gain Amplifier). However, if a difference between a common voltage of the CDS circuit and a common voltage of the PGA is large, there is a risk that a pixel value cannot be accurately outputted to the outside.

### BRIEF DESCRIPTION OF THE DRAWINGS

FIG. 1 is a block diagram showing a schematic configuration of an image sensor.

FIG. 2 is a circuit diagram showing an example of an internal configuration of the pixel 1.

FIG. 3 is a diagram schematically showing a relationship between the intensity of the light emitted on the pixel 1 and the signal voltage Vsig generated by the pixel 1.

FIG. 4 is a diagram showing each circuit of the CDS circuit 3 to the PGA 6 in more detail.

FIGS. 5A and 5B are graphs showing a relationship between each voltage and the single voltage Vsig.

FIG. 6 is a circuit diagram showing an example of a voltage selector 4a included in the adjustment voltage generator 4.

FIG. 7 is a waveform chart of each signal and voltage in FIGS. 4 and 6.

FIGS. 8A and 8B are graphs showing a relationship between each voltage and the single voltage Vsig.

FIG. 9 is a block diagram showing an example of an internal configuration of the adjustment voltage generator 4.

FIG. 10 is a circuit diagram showing an example of the reference voltage generation circuit 4c.

FIG. 11 is a circuit diagram showing another example of the reference voltage generation circuit 4c.

FIG. 12 is a block diagram showing an example of an internal configuration of the adjustment voltage generator 4.

FIG. 13 is a circuit diagram showing an example of the reference voltage generation circuit 4c.

FIG. 14 is a circuit diagram showing an example of the toleration voltage guarantee circuit 8.

FIG. 15 is a schematic timing chart of the bias KBIAS supplied to the toleration voltage guarantee circuit 8.

### DETAILED DESCRIPTION

In general, according to one embodiment, a semiconductor integrated circuit includes: a CDS (Correlated Double Sampling) circuit; and an adjustment voltage generator. The CDS circuit has a first capacitor and a second capacitor. The first capacitor has a first electrode and a second electrode. The second capacitor has a third electrode and a fourth electrode. The CDS circuit is configured to hold a voltage corresponding to light intensity as a signal voltage. The adjustment voltage generator is configured to supply an adjustment voltage to the CDS circuit. A first signal voltage is supplied to the first electrode, and a second signal voltage is supplied to the third electrode. The second electrode and the fourth electrode are commonly connected and supplied with the adjustment voltage from the adjustment voltage generator.

Hereinafter, embodiments will be specifically described with reference to the drawings.

### First Embodiment

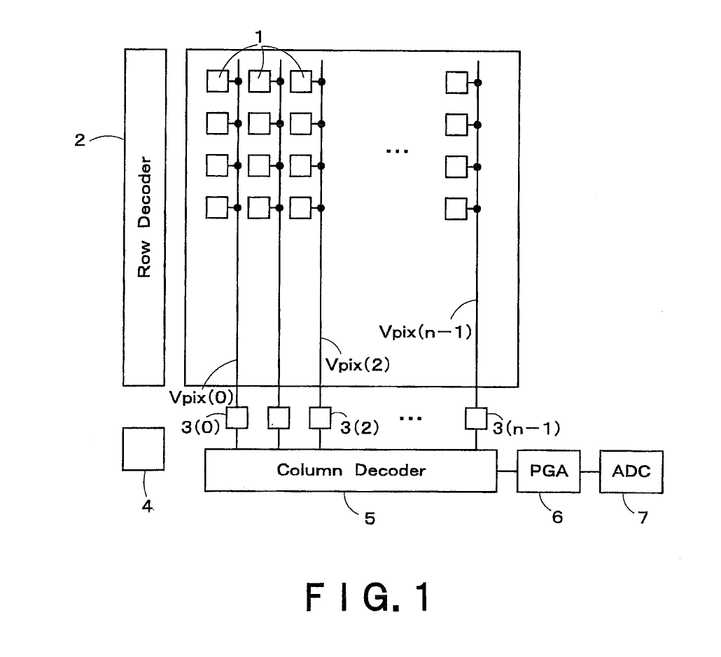

FIG. 1 is a block diagram showing a schematic configuration of an image sensor. The image sensor includes pixels 1, a low decoder 2, a CDS circuit 3, an adjustment voltage generator 4, a column decoder 5, a PGA (amplification circuit) 6, and an ADC (Analog to Digital Converter) 7.

The pixels 1 are arranged in a matrix form. The number of pixels in the horizontal (column) direction is n (for example, 1720 columns) and the number of pixels in the vertical (row) direction is m (for example, 832 rows). Each pixel 1 generates an analog voltage Vpix according to the intensity of emitted light. The pixel 1 belonging to k-th column outputs the generated voltage Vpix to a signal line Vpix(k). In the description below, the code “Vpix(k)” and the like are used as a name of a signal line (or a terminal) as well as a voltage value of the signal line (or the terminal).

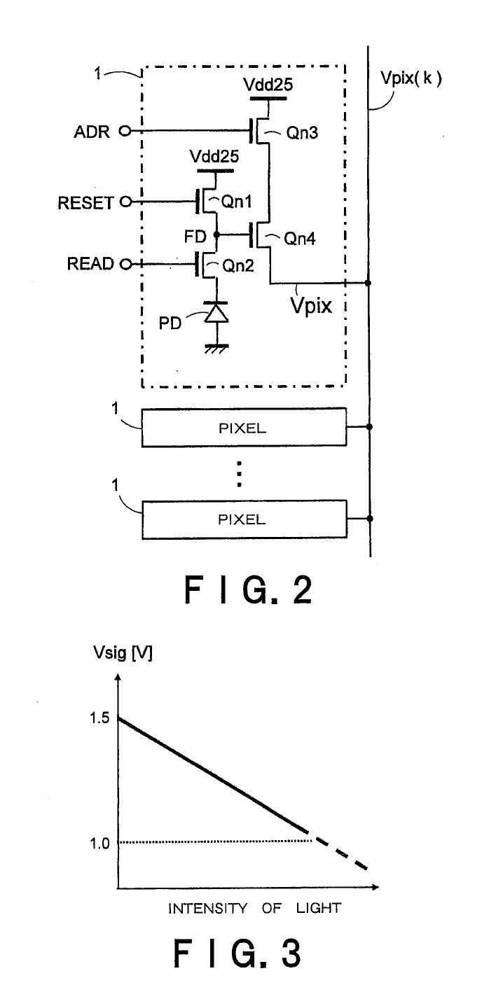

FIG. 2 is a circuit diagram showing an example of an internal configuration of the pixel 1. Note that, the circuit diagram shown in FIG. 2 is only an example, and there may be various modified circuits.

The pixel 1 includes nMOS transistors Qn1 to Qn4 and a photodiode PD that performs photoelectric conversion. Regarding the transistor Qn1, the drain is connected to a power supply terminal Vdd25, a reset signal RESET is inputted into the gate, and the source is connected to a floating diffusion FD. Regarding the transistor Qn2, the drain is connected to the floating diffusion FD, a read signal READ is inputted into the gate, and the source is connected to the cathode of the photodiode PD. The anode of the photodiode PD is connected to the ground terminal.

Regarding the transistor Qn3, the drain is connected to the power supply terminal Vdd25, an address signal ADR is inputted into the gate, and the source is connected to the drain of the transistor Qn4. Regarding the transistor Qn4, the gate is connected to the floating diffusion FD and a voltage Vpix is generated from the source. The source of the transistor Qn4 is connected to the signal line Vpix(k) and the voltage Vpix is outputted to the signal line Vpix(k).

In the description below, it is assumed that the power supply voltage supplied from the power supply terminal Vdd25 is 2.5V. The address signal ADR, the reset signal RESET, and the read signal READ are generated by, for example, the low decoder 2.

The pixel 1 generates a voltage Vpix when no light is emitted (hereinafter referred to as a “reset voltage Vres”) and a voltage Vpix when light is emitted (hereinafter referred to as a “signal voltage Vsig”) to perform a so-called correlated double sampling. Specifically, the pixel 1 operates as described below.

First, the reset signal RESET is set to high. Thereby, the transistor Qn1 is turned on and the floating diffusion FD is initialized to a predetermined voltage. Thereafter, the reset signal RESET is set to low. Then, the read signal READ is set to high while no light is emitted on the pixel 1 in order to generate the reset voltage Vres. Thereby, the transistor Qn2 is turned on. At this time, only a negligible current flows in the photodiode PD, and thus, the voltage of the floating diffusion FD hardly drops. Here, when the address signal ADR is set to high, the transistor Qn3 is turned on. Thereby, the reset voltage Vres corresponding to the voltage of the floating diffusion FD is outputted to the signal line Vpix(k).

To generate the signal voltage Vsig, an operation similar to the above operation is performed while light is emitted on the pixel 1. A current corresponding to the intensity (brightness) of the emitted light flows in the photodiode PD. The higher the intensity of the light is, the larger the current is. Therefore, as the intensity of the light is higher, the voltage of the floating diffusion FD becomes lower. The signal voltage Vsig corresponding to the voltage of the floating diffusion FD is outputted to the signal line Vpix(k).

FIG. 3 is a diagram schematically showing a relationship between the intensity of the light emitted on the pixel 1 (horizontal axis, any unit can be used) and the signal voltage Vsig generated by the pixel 1 (vertical axis, unit is “V”). As known from the above description, the higher the intensity of the light, the lower the signal voltage Vsig. In the description below, as an example, it is assumed that the reset voltage Vres is 1.5 V and the signal voltage Vsig when high intensity light is emitted is about 1.0 V.

Referring back to FIG. 1, the low decoder 2 sequentially selects one of m rows arranged in the vertical direction. In other words, the low decoder 2 sets the address signal ADR inputted into n pixels 1 belonging to a certain row to high. Thereby, the voltages Vpix generated by the n pixels 1 are read to the signal lines Vpix(k), respectively.

One CDS circuit 3 is arranged for pixels in one column, so that a total of n CDS circuits 3 are arranged. In other words, the CDS circuit 3(0) to the CDS circuit 3(n-1) are provided corresponding to the signal lines Vpix(0) to Vpix(n-1), respectively. The CDS circuits 3 samples and temporarily holds the reset voltage Vres and the signal voltage Vsig which are read from the pixel 1. By holding both the reset voltage Vres and the signal voltage Vsig and amplifying a difference between both voltages later, it is possible to suppress the effect of variation of the reset voltages Vres among the pixels 1.

The adjustment voltage generator 4 generates an adjustment voltage Vbp and supplies the adjustment voltage Vbp to n CDS circuits 3(0) to 3(n-1). The adjustment voltage Vbp is a voltage to adjust a common voltage Vcm_cds of the CDS circuit 3. The adjustment voltage generator 4 is one of the features of the present embodiment. The adjustment voltage generator 4 will be described later in detail.

The column decoder 5 sequentially selects one of n CDS circuits 3(0) to 3(n-1) and supplies the reset voltage Vres and the signal voltage Vsig held by the selected CDS circuit 3 to the PGA 6.

The PGA 6 is an amplifier that amplifies the difference between the reset voltage Vres and the signal voltage Vsig. The PGA 6 outputs a voltage corresponding to the signal voltage Vsig as differential voltages Voutp and Voutn.

The ADC 7 converts the differential voltages Voutp and Voutn into a digital signal.

By the selection operations of the low decoder 2 and the column decoder 5 described above, a digital signal representing the intensity of the light emitted on each pixel 1 is serially read.

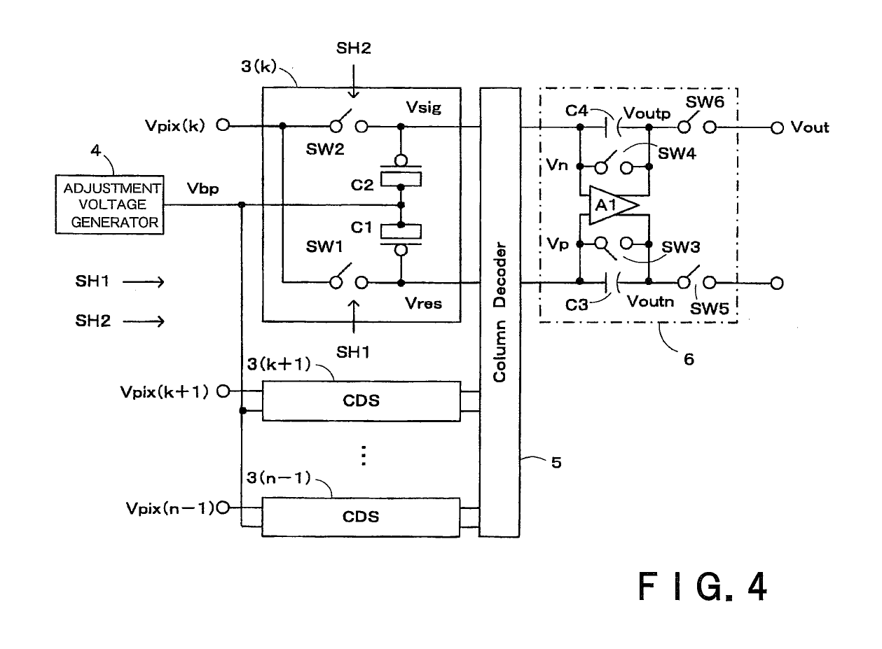

FIG. 4 is a diagram showing each circuit of the CDS circuit 3 to the PGA 6 in more detail. In the description below, the n CDS circuits 3(0) to 3(n-1) have the same configuration, so that a CDS circuit 3(k) will be described as a representative of the CDS circuits 3(0) to 3(n-1).

A voltage of the signal line Vpix(k) is inputted into the CDS circuit 3(k). The CDS circuit 3(k) outputs the reset voltage Vres and the signal voltage Vsig from two output terminals to the PGA 6 through the column decoder 5.

The CDS circuit 3(k) includes switches SW1 and SW2 and pMOS capacitors C1 and C2. The signal line Vpix(k) is inputted into the CDS circuit 3(k), and the signal line Vpix(k) is connected to the gate electrode (hereinafter referred to as a “control electrode” or a “first electrode”) of the capacitor C1 (first pMOS capacitor) through the switch SW1 and is also connected to the gate electrode (hereinafter referred to as a “control electrode” or a “third electrode”) of the capacitor C2 (second pMOS capacitor) through the switch SW2. The substrate side electrode (hereinafter referred to as a “reference electrode” or a “second electrode”) of the capacitor C1 is connected to the substrate side electrode (hereinafter referred to as a “reference electrode” or a “fourth electrode”) of the capacitor C2. The adjustment voltage Vbp generated by the adjustment voltage generator 4 is inputted into the portion where the substrate side electrode of the capacitor C1 is connected to the substrate side electrode of the capacitor C2.

The switches SW1 and SW2 are controlled by control signals SH1 and SH2, respectively. The control signals SH1 and SH2 may be generated by, for example, a control circuit not shown in FIG. 4 or may be generated from the outside of the image sensor.

Here, the common voltage Vcm_cds of the CDS circuit 3 is an average voltage of the two output terminals of the CDS circuit 3. In other words, the common voltage Vcm_cds is an average voltage of the control electrode of the capacitor C1 and the control electrode of the capacitor C2. In more other words, the common voltage Vcm_cds is an average voltage of the reset voltage Vres and the signal voltage Vsig.

The CDS circuit 3(k) and the column decoder 5 operate as described below.

First, the reset voltage Vres of the pixel 1 belonging to one row is read into the signal line Vpix(k) by a control of the row decoder 2. In this state, the control signal SH1 is set to high and the switch SW1 is turned on. Thereby, the reset voltage Vres is sampled and electric charge corresponding to the reset voltage Vres is accumulated between the electrodes of the capacitor C1. Thereafter, when the control signal SH1 is set to low, the switch SW1 is turned off and the reset voltage Vres is held.

Subsequently, the signal voltage Vsig of the pixel 1 belonging to one row is read into the signal line Vpix(k) by a control of the row decoder 2. In this state, the control signal SH2 is set to high and the switch SW2 is turned on. Thereby, the signal voltage Vsig is sampled and electric charge corresponding to the signal voltage Vsig is accumulated between the electrodes of the capacitor C2. Thereafter, when the control signal SH2 is set to low, the switch SW2 is turned off and the signal voltage Vsig is held.

The operation described above is performed commonly and simultaneously by all the CDS circuits 3(0) to 3(n-1). Subsequently, one of the CDS circuits 3(0) to 3(n-1) is sequentially selected by the column decoder 5. Thereby, the reset voltage Vres is supplied to the positive input terminal Vp of the PGA 6, and the signal voltage Vsig is supplied to the negative input terminal Vn of the PGA 6.

The PGA 6 amplifies a difference between the reset voltage Vres inputted into the positive input terminal Vp and the signal voltage Vsig inputted into the negative input terminal Vn and outputs voltages as the differential voltages Voutp and Voutn.

The PGA 6 includes a differential amplifier A1, switches SW3 to SW6, and capacitors C3 and C4. The positive input terminal Vp and the negative input terminal Vn of the PGA 6 are respectively connected to the positive input terminal and the negative input terminal of the differential amplifier A1. The switch SW3 and the capacitor C3 are connected in parallel between the positive input terminal and the negative output terminal of the differential amplifier A1. Similarly, the switch SW4 and the capacitor C4 are connected in parallel between the negative input terminal and the positive output terminal of the differential amplifier A1. The voltage Voutp of the positive output terminal and the voltage Voutn of the negative output terminal of the differential amplifier A1 are outputted to the ADC 7 through the switches SW5 and SW6 respectively at an appropriate timing.

In the description below, an example will be described in which a power supply voltage Vdd15 supplied to the differential amplifier A1 is 1.5 V, and thus, the differential amplifier A1 can output a voltage of 0 to 1.5 V. The amplification gain of the differential amplifier A1 can be variably adjusted according to the capacitors C3 and C4. The switches SW3 and SW4 may be controlled by, for example, a control circuit not shown in FIG. 4 or may be controlled from the outside of the image sensor.

The PGA 6 operates as described below. First, the switches SW3 and SW4 are turned on in advance and the input terminals and the output terminals of the differential amplifier A1 are short-circuited. Further, at this timing, common mode feedback is performed. Thereby, an input common voltage Vcm_pga_in and an output common voltage Vcm_pga_out of the PGA 6 are set to ½ of the power supply voltage Vdd15 of the PGA 6, that is, 0.75 V, as an initial value.

Here, the input common voltage Vcm_pga_in of the PGA 6 is an average voltage of the input terminals Vp and Vn of the PGA 6. The output common voltage Vcm_pga_out of the PGA 6 is an average voltage of the output terminals Voutp and Voutn of the PGA 6.

Subsequently, while the switches SW3 and SW4 are turned off, the PGA 6 receives the reset voltage Vres and the signal voltage Vsig from the CDS circuit 3 through the column decoder 5. Thereby, the differential amplifier A1 performs a differential amplification operation and outputs the voltage Voutp from the positive output terminal and the voltage Voutn from the negative output terminal. The voltages Voutp and Voutn are represented by the formulas (1) and (2) below.

Voutp=Vcm_{—}pga_out+(Vres−Vsig)/2 (1)

Voutn=Vcm_{—}pga_out−(Vres−Vsig)/2 (2)

In the manner as described above, the analog voltages Voutp and Voutn corresponding to the signal voltage Vsig outputted from one pixel 1 can be obtained.

Here, the differential amplifier A1 not only amplifies the difference between the reset voltage Vres and the signal voltage Vsig, but also amplifies a difference between the common voltage Vcm_cds (=(Vres+Vsig)/2) of the CDS circuit 3 and the input common voltage Vcm_pga_in of the differential amplifier A1 and affects the output common voltage Vcm_pga_out. Specifically, when the initial value of the output common voltage Vcm_pga_out of the PGA 6 is Vcm0 (=0.75 V), the output common voltage Vcm_pga_out is represented by the following formula (3).

$$\begin{matrix}Vcm\_pga \_out = Vcm 0 + ( Vcm\_pga \_in - Vcm\_cds ) \\ = Vcm 0 + \{ Vcm\_pga \_in - ( Vres + Vsig ) \text{/} 2 )\end{matrix} \qquad ( 3 )$$

If the common voltage Vcm_cds of the CDS circuit 3 is substantially the same as the input common voltage Vcm_pga_in of the differential amplifier A1, even when the difference between the common voltage Vcm_cds and the input common voltage Vcm_pga_in is amplified, the output common voltage Vcm_pga_out is not so much affected.

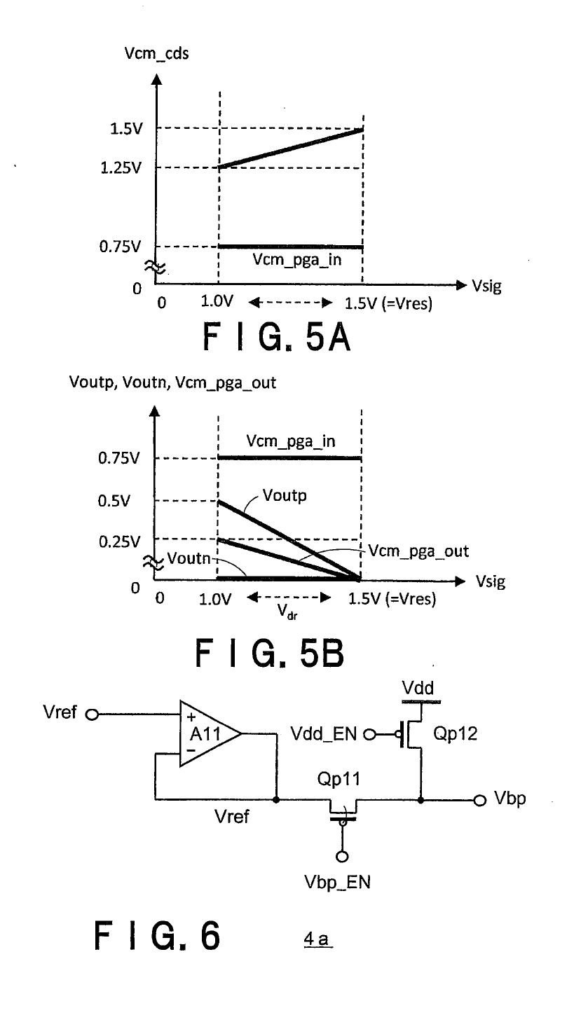

However, the common voltage Vcm_cds is unnecessarily substantially the same as the common voltage Vcm_pga_in. Hereinafter, by using numerical examples in the present embodiment, an operation of the PGA 6 when the two common voltages are not equal will be described with reference to FIG. 5.

FIG. 5A is a diagram showing a relationship between the common voltage Vcm_cds of the CDS circuit 3 (vertical axis) and the signal voltage Vsig (horizontal axis). As shown in FIG. 3, the reset voltage Vres is 1.5 V and the signal voltage Vsig is 1 V to 1.5 V. Therefore, the common voltage Vcm_cds (=(Vres+Vsig)/2) of the CDS circuit 3 is 1.25 V to 1.5 V. On the other hand, as described above, the input common voltage Vcm_pga_in of the differential amplifier A1 is 0.75 V. Therefore, the difference between these voltages is −0.75 V (@Vsig=1.5V) to −0.5 V (@Vsig=1.0 V), which is not necessarily small.

As shown in the above formula (3), the difference between the common voltage Vcm_cds and the common voltage Vcm_pga_in is added to the initial value 0.75 V of the output common voltage Vcm_pga_out of the PGA 6.

FIG. 5B is a diagram showing a relationship between the voltages Voutp, Voutn and the common voltage Vcm_pga_out (which are represented by vertical axis) and the signal voltage Vsig (which is represented by horizontal axis). As shown in FIG. 5B, the common voltage Vcm_pga_out becomes 0 V (@Vsig=1.5 V) to 0.25 V (@Vsig=1.0 V) due to the difference between the common voltage Vcm_cds of the CDS circuit 3 and the input common voltage Vcm_pga_in of the PGA 6. As a result, the minimum value of the voltages Voutp and Voutn is 0 V by the above formulas (1) and (2).

The differential amplifier A1 not necessarily can output the voltage near 0 V linearly and it is difficult for the differential amplifier A1 to output a voltage lower than or equal to 0 V.

Therefore, when the signal voltage Vsig is near 1.5 V (that is, when the intensity of light is low), the PGA 6 not necessarily can generate the voltages Voutp and Voutn corresponding to the signal voltage Vsig. This is caused because the common voltage Vcm_cds of the CDS circuit 3 and the input common voltage Vcm_pga_in of the PGA 6 are different from each other.

Therefore, it can be conceived to suppress the difference between the two common voltages by inserting a buffer into an output stage of the CDS circuit 3 and further adding a capacitor between the buffer and the differential amplifier A1. However, when the buffer is provided, distortion may occur due to the buffer and the size of the CDS circuit 3 increases. In particular, n CDS circuits 3 are provided, and thus, the total size of the image sensor significantly increases.

Therefore, in the present embodiment, one adjustment voltage generator 4 is provided. Thereby, it is intended that while suppressing the increase of the size, the reset voltage Vres and the signal voltage Vsig are lowered, and as a result, the common voltage Vcm_cds of the CDS circuit 3 is lowered.

FIG. 6 is a circuit diagram showing an example of a voltage selector 4a included in the adjustment voltage generator 4. The adjustment voltage generator 4 includes a differential amplifier A11, pMOS transistors Qp11 and Qp12. A reference voltage Vref is input into the positive input terminal of the differential amplifier A11 and the negative input terminal is short-circuited to the outputted terminal. Therefore, the differential amplifier A11 outputs the reference voltage Vref.

The drains of the transistors Qp11 and Qp12 are connected to the output terminal Vbp at which the adjustment voltage Vbp is generated. Regarding the transistor Qp11, the source is connected to the output terminal of the differential amplifier A11 and a signal Vbp_EN is inputted into the gate. Regarding the transistor Qp12, the source is connected to the power supply terminal and a signal Vdd_EN is inputted into the gate. The signals Vbp_EN and Vdd_EN may be generated by, for example, a control circuit not shown in FIG. 6 or may be generated from the outside of the image sensor.

When the signal Vdd_EN is set to low, the transistor Qp12 is turned on and the power supply voltage Vdd is outputted as the adjustment voltage Vbp. On the other hand, when the signal Vbp_EN is set to low, the transistor Qp11 is turned on and the reference voltage Vref is outputted as the adjustment voltage Vbp.

In the description below, an example will be described in which a power supply voltage supplied from the power supply terminal Vdd is 2.5 V (first voltage) which is the same as the power supply voltage Vdd25 of the pixel 1, and the reference voltage Vref is 2.0 V (second voltage). In the present embodiment, since the common voltage of the CDS circuit 3 is higher than the common voltage of the PGA 6, the reference voltage Vref is set to lower than the power supply voltage Vdd.

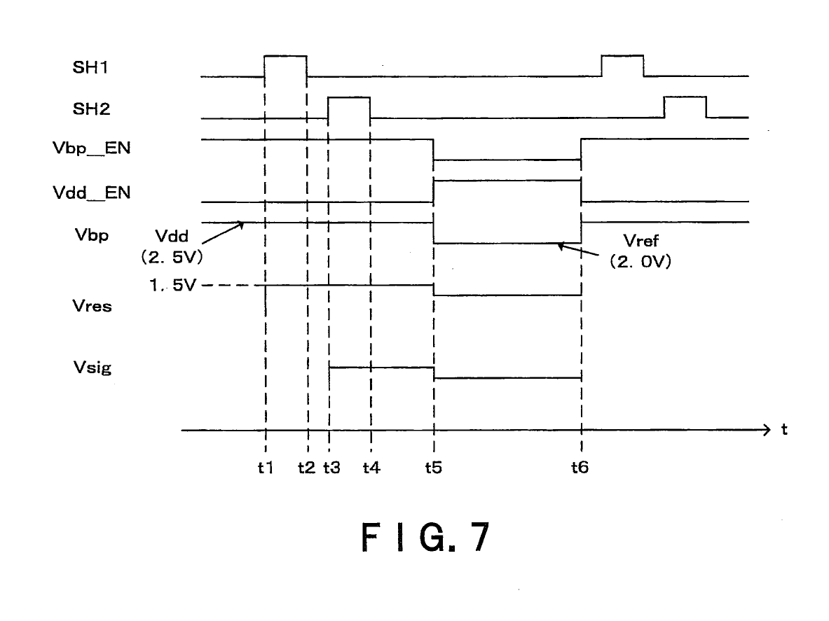

FIG. 7 is a waveform chart of each signal and voltage in FIGS. 4 and 6.

The signal SH1 is set to on at the time t1. Thereby, the reset voltage Vres is sampled and electric charge corresponding to the reset voltage Vres is accumulated in the capacitor C1. Thereafter, the signal SH1 is set to off at the time t2. Thereby, the reset voltage Vres is held.

The signal SH2 is set to on at the time t3. Thereby, the signal voltage Vsig is sampled and electric charge corresponding to the signal voltage Vsig is accumulated in the capacitor C2. Thereafter, the signal SH2 is set to off at the time t4. Thereby, the signal voltage Vsig is held.

Until time t4, the signal Vbp_EN is high and the signal Vdd_EN is low. Therefore, the adjustment signal Vbp is equal to the power supply voltage Vdd, which is 2.5 V.

Subsequently, at the time t5, the signal Vbp_EN is set to low and the signal Vdd_EN is set to high. Thereby, the adjustment signal Vbp is set to 2.0 V, which is equal to the reference signal Vref. Therefore, the adjustment signal Vbp drops by 0.5 V.

Since the amounts of electric charge accumulated in the capacitors C1 and C2 do not change, the voltage difference between the electrodes of the capacitors C1 and C2 is constant. Therefore, both the reset voltage Vres and the signal voltage Vsig, which are held, also drop by 0.5 V by capacitive coupling. As a result, the common voltage Vcm_cds of the CDS circuit 3 also drops by 0.5 V. The adjustment of the common voltage Vcm_cds of the CDS circuit 3 performed in this way (in the present example, the voltage is dropped) is simply called “common voltage adjustment” in the description below.

While both the reset voltage Vres and the signal voltage Vsig drop by 0.5 V, the column decoder 5 selects one of the CDS circuits 3(0) to 3(n-1) and supplies the reset voltage Vres and the signal voltage Vsig held by the selected CDS circuit 3 to the PGA 6. More specifically, between time t5 and t6, the column decoder 5 sequentially selects one of the CDS circuits 3(0) to 3(n-1).

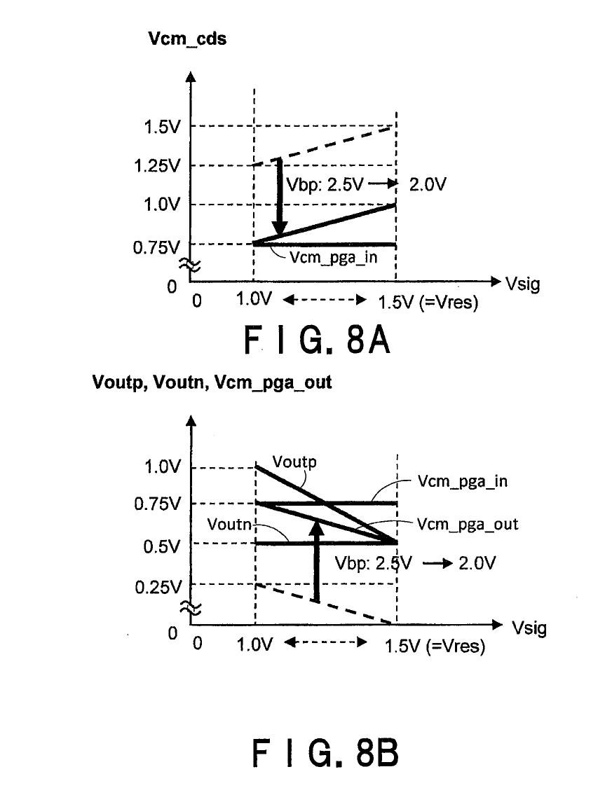

FIG. 8A is a diagram showing a relationship between the common voltage Vcm_cds of the CDS circuit 3 (vertical axis) and the signal voltage Vsig (horizontal axis). The dashed line in FIG. 8A represents the relationship when the common voltage adjustment is not performed and the solid lines represent the relationship when the common voltage adjustment is performed. As shown in FIG. 8A, when the common voltage adjustment is performed, it is possible to drop the common voltage Vcm_cds of the CDS circuit 3 by 0.5 V, so that the common voltage Vcm_cds becomes 0.75 V (@Vsig=1.0 V) to 1.0 V (@Vsig=1.5 V)

In this way, it is possible to bring the common voltage Vcm_cds of the CDS circuit 3 to near 0.75 V, which is the input common voltage Vcm_pga_in of the PGA 6. In other words, the difference between the two common voltages is −0.25 V (@Vsig=1.5 V) to 0 V (@Vsig=1.0 V). As a result, it is possible to reduce influence on the output common voltage Vcm_pga_out of the PGA 6.

FIG. 8B is a diagram showing a relationship between the voltages Voutp, Voutn and the common voltage Vcm_pga_out (which are represented by vertical axis) and the signal voltage Vsig (which is represented by horizontal axis). The dashed line (only the Vcm_pga_out) in FIG. 8B represents the relationship when the common voltage adjustment is not performed and the solid lines represent the relationship when the common voltage adjustment is performed. As shown in FIG. 8B, the common voltage Vcm_pga_out becomes 0.5 V (@Vsig=1.5 V) to 0.75 V (@Vsig=1.0 V) due to the difference between the common voltage Vcm_cds of the CDS circuit 3 and the input common voltage Vcm_pga_in of the PGA 6.

When the common voltage adjustment is not performed, the common voltage Vcm_pga_out is 0 V to 0.25 V (@Vsig=1.0 V) (dashed line in FIG. 8B). Compared with this, when the common voltage adjustment is performed, it is possible to set the common voltage Vcm_pga_out to near the center between 0 V and 1.5 V, which is an operating voltage of the PGA 6.

Therefore, the minimum value of the voltages Voutp and Voutn is 0.5 V and the maximum value of the voltages Voutp and Voutn is 1.0 V by the above formulas (1) and (2). There are sufficient margins between the minimum value 0.5 V and 0 V and between the maximum value 1.0 V and 1.5 V. Therefore, the PGA 6 can generate the output voltages Vp and Vn corresponding to the signal voltage Vsig.

The reason why the amount of voltage drop of the common voltage Vcm_cds of the CDS circuit 3 is set to 0.5 V is to set the output common voltage Vcm_pga_out of the PGA 6 when the signal voltage Vsig is 1.0 V (that is, when the intensity of the light is high) to 0.75 V, which is the center of the operating voltage. Thereby, it is possible to operate the output voltage Voutp between 0.5 V and 1.0 V, the center of which is 0.75 V.

More generally, the amount of voltage drop dVbp of the common voltage Vcm_cds can be determined as described below. The output common voltage of the PGA 6 when the reset voltage Vres is constant and CDS circuit 3 common mode feedback is performed (that is, ½ of the power supply voltage Vdd15 of the PGA 6) is defined as Vcm0, and the signal voltage Vsig when the difference between the reset voltage Vres and the signal voltage Vsig is maximum is defined as Vsig_max.

When the PGA 6 performs a differential amplification operation after the reset voltage Vres and the signal voltage Vsig_max are dropped by dVbp by the common voltage adjustment, the output common voltage Vcm_pga_out of PGA 6 is represented by the following formula (4).

$$\begin{matrix}Vcm\_pga \_out = Vcm 0 + ( Vcm\_pga \_in - Vcm\_cds ) \\ = Vcm 0 + \{ Vcm\_pga \_in - ( Vres + Vsig\_max ) \text{/} 2 \}\end{matrix} \qquad ( 4 )$$

In a simple term, it is possible to lower the output common voltage Vcm_pga_out of PGA 6 by the amount of voltage drop dVbp from the formula (3) described above.

The amount of voltage drop dVbp is set so that the left side of the formula (4) is Vcm0. Thus, the following formula (5) is established.

dVbp=(Vres+Vsig_max)/2−Vcm0 (5)

Here, when the maximum value of the difference between the reset voltage Vres and the signal voltage Vsig is defined as Vsig_res_diff (=Vres−Vsig_max), the formula (5) described above can be also represented as the formula (6) below.

dVbp=Vres−(Vcm0+Vsig_{—}res_{—}diff/2) (6)

In the example of the present embodiment, Vres=1.5 V, Vsig_res_diff=0.5 V, and Vcm0=0.75 V, and thus, Vbp=0.5 V can be obtained.

As described above, in the first embodiment, the adjustment voltage generator 4 is provided and the common voltage of the CDS circuit 3 is adjusted to be near the common voltage of the PGA 6. Therefore, it is possible to accurately generate the output voltages Vp and Vn corresponding to the signal voltage Vsig.

### Second Embodiment

In the first embodiment described above, it is assumed that the reset voltage Vres is constant, that is, 1.5 V. However, actually, the reset voltage Vres is not necessarily constant due to variation of devices and the like and may be, for example, 1.4 V or 1.6 V.

Therefore, in the second embodiment described below, it is intended to generate an adjustment voltage Vbp that can cancel the variation of the reset voltage.

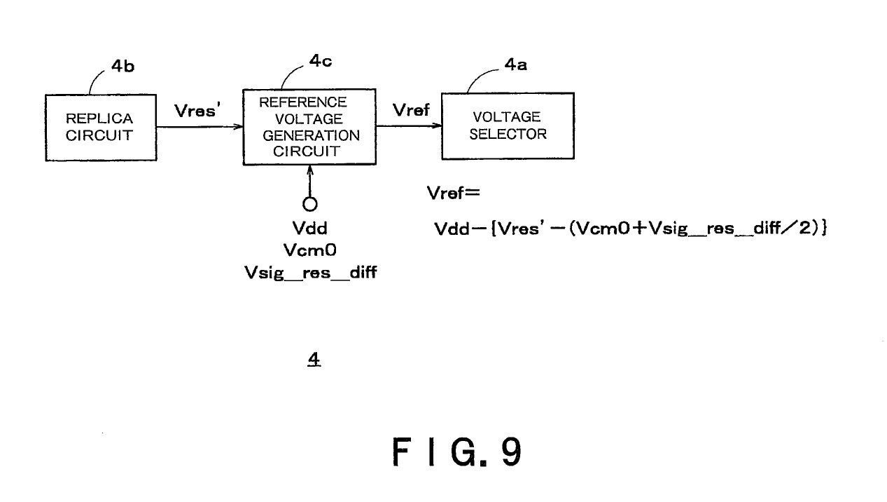

FIG. 9 is a block diagram showing an example of an internal configuration of the adjustment voltage generator 4. The adjustment voltage generator 4 includes a replica circuit 4b and a reference voltage generation circuit 4c in addition to the voltage selector 4a illustrated in FIG. 6.

The replica circuit 4b has the same circuit configuration as that of the pixel 1. Therefore, the replica circuit 4b has the same characteristics as those of the pixel 1, so that the replica circuit 4b can generate a reset voltage Vres' equal to the reset voltage Vres generated by the pixel 1. For example, when the reset voltage Vres is 1.4 V instead of 1.5 V, the reset voltage Vres' is also 1.4 V.

The reference voltage generation circuit 4c receives the reset voltage Vres' from the replica circuit 4b. The reference voltage generation circuit 4c generates the reference voltage Vref represented by the formula (6) described below based on the reset voltage Vres', the power supply voltage Vdd of the voltage selector 4a, the initial value Vcm0 of the output common voltage of the PGA 6, and the Vsig_res_diff which is the maximum value of the difference between the reset voltage Vres and the signal voltage Vsig.

Vref=Vdd−{Vres′−(Vcm0+Vsig_{—}res_{—}diff/2)} (6)

In this way, an appropriate reference voltage can be generated according to the actual reset voltage Vres'. The generated reference voltage Vref is supplied to the voltage selector 4a, and the power supply voltage Vdd or the reference voltage Vref is outputted to the CDS circuit 3 at the timing shown in FIG. 7.

As an example, it is assumed that the reset voltage Vres is 1.4 V instead of 1.5 V. When the common voltage adjustment is not performed, the common voltage Vcm_cds of the CDS circuit 3 is lower than the voltage shown in FIG. 5A by 0.1 V and is 1.15 V to 1.4 V.

On the other hand, since Vdd=2.5 V, Vcm0=0.75 V, and Vsig_res_diff=0.5V, Vref=2.1 V, that is, dVbp=0.4, is obtained by the formula (6). Thus, it is possible to lower the common voltage Vcm_cds of the CDS circuit 3 by 0.4 V by performing the common voltage adjustment.

As a result, the common voltage Vcm_cds becomes 0.75 V to 1.0 V. In other words, even when the reset voltage Vres is 1.4 V instead of 1.5 V, the same common voltage Vcm_cds as that shown in FIG. 8A can be generated. In this way, the variation of the reset voltage Vres can be canceled.

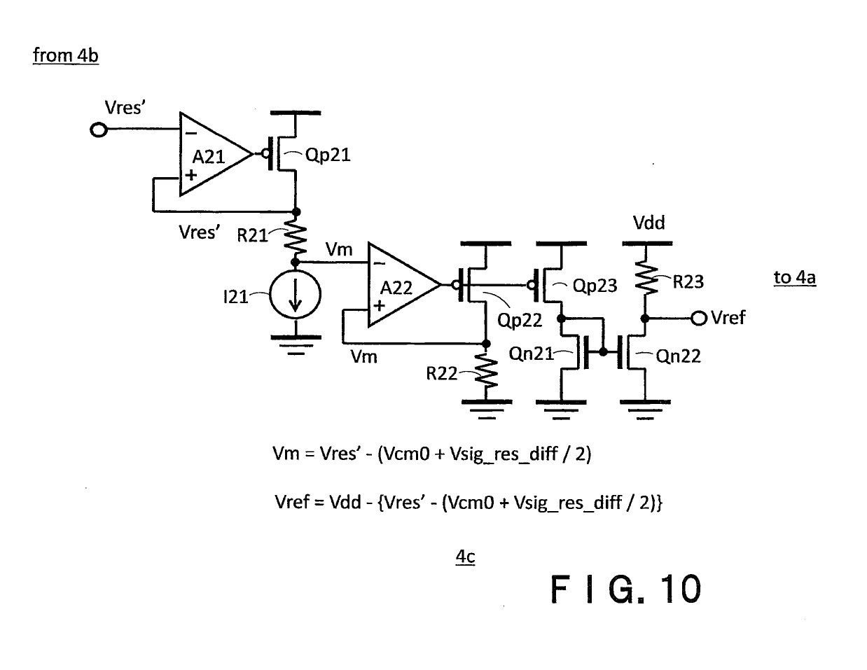

FIG. 10 is a circuit diagram showing an example of the reference voltage generation circuit 4c.

The reference voltage generation circuit 4c includes a differential amplifier A21, a pMOS transistor Qp21, a resistor R21, and a current source 121. The reset voltage Vres′ generated by the replica circuit 4b is inputted into the negative input terminal of the differential amplifier A21. The transistor Qp21, the resistor R21, and the current source 121 are connected in series between the power supply terminal and the ground terminal. The gate and the drain of the transistor Qp21 are connected to the output terminal and the positive input terminal of the differential amplifier A21, respectively.

The reset voltage Vres′ is generated at the positive input terminal of the differential amplifier A21 by the feedback of the differential amplifier A21 and the transistor Qp21. By appropriately adjusting the resistance value of the resistor R21 and the current value of the current source 121, the voltages of these connection terminals between the resistor R21 and the current source 121 can be set to an intermediate voltage Vm=Vres′−(Vcm0+Vsig_res_diff/2).

The reference voltage generation circuit 4c further includes a differential amplifier A22, a pMOS transistor Qp22, and a resistor R22. The intermediate voltage Vm is inputted into the negative input terminal of the differential amplifier A22. The transistor Qp22 and the resistor R22 are connected in series between the power supply terminal and the ground terminal. The gate and the drain of the transistor Qp22 are connected to the output terminal and the positive input terminal of the differential amplifier A22, respectively.

The reference voltage generation circuit 4c further includes a pMOS transistor Qp23, nMOS transistors Qn21, Qn22, and a resistor R23. The transistors Qp23 and Qn21 are connected in series between the power supply terminal and the ground terminal. The gate of the transistor Qp23 is connected to the output terminal of the differential amplifier A22 and the gate of the transistor Qp22. The gate of the transistor Qn21 is short-circuited to the drain thereof. The resistor R23 and the transistor Qn22 are connected in series between the power supply terminal and the ground terminal. The gate of the transistor Qn22 is connected to the gate of the transistor Qn21. The reference voltage Vref is outputted from the drain of the transistor Qn22.

The intermediate voltage Vm is generated at the positive input terminal of the differential amplifier A22 by the feedback of the differential amplifier A22 and the transistor Qp22. A current proportional to the intermediate voltage Vm flows in the resistor R22.

A current mirror is formed by the transistors Qp22, Qp23, Qn21, and Qn22, and the same current as that flowing in the resistor R22 also flows in the resistor R23. Therefore, a voltage obtained by subtracting the intermediate voltage Vm from the power supply voltage Vdd, that is, the reference voltage Vref of the above formula (6), is generated.

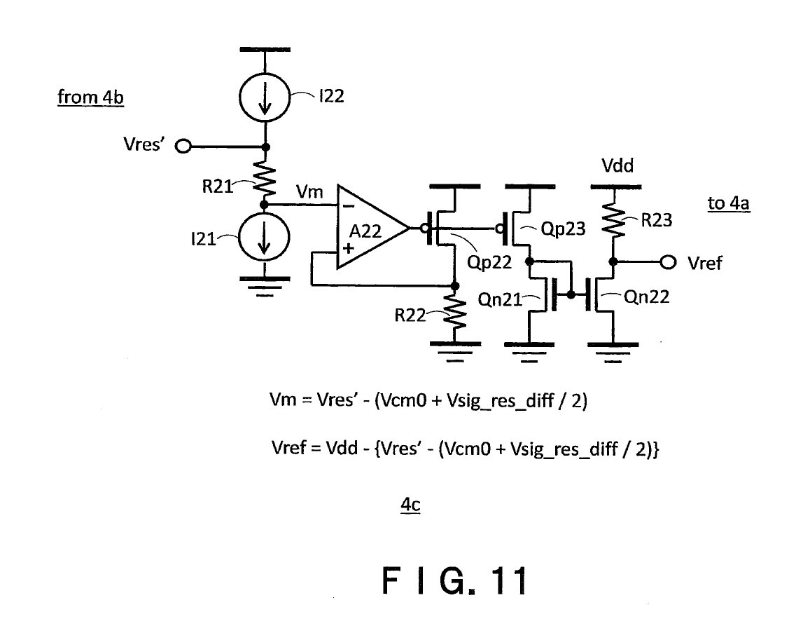

FIG. 11 is a circuit diagram showing another example of the reference voltage generation circuit 4c. A major difference from FIG. 10 is that the differential amplifier A21 and the transistor Qp21 are removed and a current source 122 is provided. The reset voltage Vres′ is inputted into a connection node between the current source 122 and the resistor R21. The basic operation is similar to that of the reference voltage generation circuit 4c shown in FIG. 10.

The differential amplifier A21 is removed in the circuit shown in FIG. 11, so that the circuit area can be reduced. Although the reset voltage Vres' may vary somewhat due to variation of the current source 122, the effect is extremely small.

Needless to say, various circuits, which can generate the reference voltage Vref represented by the above formula (6), can be conceived other than those shown in FIGS. 10 and 11.

As described above, in the second embodiment, the reference voltage Vref is generated corresponding to the reset voltage Vres of the pixel 1 to perform the common voltage adjustment. Therefore, it is possible to more accurately generate an output voltage corresponding to the signal voltage Vsig.

### Third Embodiment

In the first and the second embodiments described above, it is assumed that the initial value Vcm0 of the output common voltage of the PGA 6 is constant, that is, 0.75 V. The initial value Vcm0 is ½ of the power supply voltage Vdd15 of the PGA 6. However, the power supply voltage Vdd15 may vary in practice, and thus, the initial value Vcm0 may shift.

Therefore, in the third embodiment described below, it is intended to generate an adjustment voltage Vbp that can cancel the variation of the power supply voltage Vdd15 of the PGA 6.

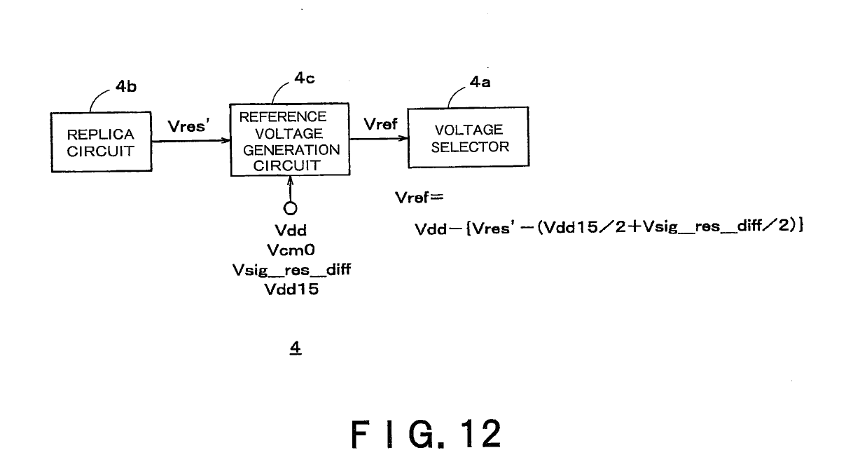

FIG. 12 is a block diagram showing an example of an internal configuration of the adjustment voltage generator 4. A major difference from FIG. 9 is that the power supply voltage Vdd15 of the PGA 6 is further inputted into the reference voltage generation circuit 4c. The reference voltage generation circuit 4c generates a reference voltage Vref represented by the formula (7) below.

Vref=Vdd−{Vres′−(Vdd15/2+Vsig_{—}res_{—}diff/2)} (7)

The formula (7) is obtained by replacing Vcm0 by Vdd15/2 in the formula (6). In this way, an appropriate reference voltage can be generated according to the actual power supply voltage Vdd15. The generated reference voltage Vref is supplied to the voltage selector 4a, and the power supply voltage Vdd or the reference voltage Vref is outputted to the CDS circuit 3 at the timing shown in FIG. 7.

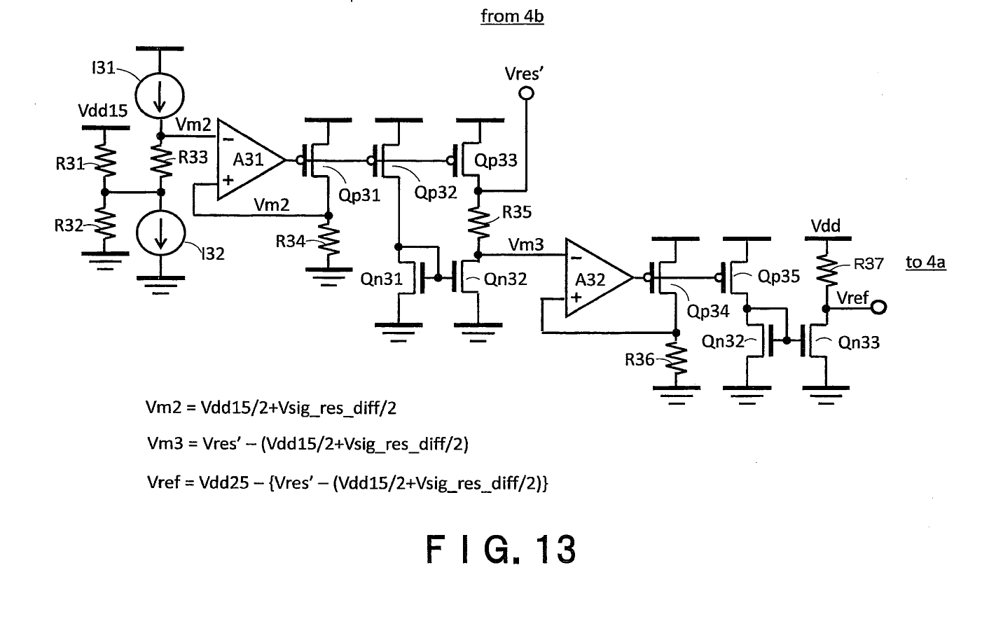

FIG. 13 is a circuit diagram showing an example of the reference voltage generation circuit 4c.

The reference voltage generation circuit 4c includes resistors R31 to R33 and current sources 131, 132. The resistors R31 and R32 have the same resistance value and are connected in series between the power supply terminal Vdd15 and the ground terminal. The current source 131, the resistor R33, and the current source 132 are connected in series between the power supply terminal and the ground terminal.

Vdd15/2 is generated at the connection node between the resistors R31 and R32 and Vdd15/2 is inputted into the connection node between the resistor R33 and the current source 132. The voltage of the connection node between the current source 131 and the resistor R33 can be set to an intermediate voltage Vm2=Vdd15/2+Vsig_res_diff/2 by appropriately adjusting the resistance value of the resistor R33 and the current values of the current sources 131 and 132.

The reference voltage generation circuit 4c further includes a differential amplifier A31, pMOS transistors Qp31 to Qp33, nMOS transistors Qn31, Qn32, and resistors R34, R35. The intermediate voltage Vm2 is inputted into the negative input terminal of the differential amplifier A31. The transistor Qp31 and the resistor R34 are connected in series between the power supply terminal and the ground terminal. The gate and the drain of the transistor Qp31 are connected to the output terminal and the positive input terminal of the differential amplifier A31, respectively.

The transistors Qp32 and Qn31 are connected in series between the power supply terminal and the ground terminal. The gate of the transistor Qp32 is connected to the output terminal of the differential amplifier A31. The gate of the transistor Qn31 is short-circuited to the drain thereof. The transistor Qp33, the resistor R35, and the transistor Qn32 are connected in series between the power supply terminal and the ground terminal. The gate of the transistor Qp33 is connected to the output terminal of the differential amplifier A31 and the gates of the transistors Qp31 and Qp32. The gate of the transistor Qn32 is connected to the gate of the transistor Qn31. The reset voltage Vres′ generated by the replica circuit 4b is inputted into the connection node between the drain of the transistor Qp33 and the resistor R35.

The intermediate voltage Vm2 is generated at the positive input terminal of the differential amplifier A31 by the feedback of the differential amplifier A31 and the transistor Qp31. A current proportional to the intermediate voltage Vm2 flows in the resistor R34. A current mirror is formed by the transistors Qp31 to Qp33, Qn31, and Qn32, and the same current as that flowing in the resistor R34 also flows in the resistor R35. The reset voltage Vres′ is inputted into one end of the resistor R35. Therefore, an intermediate voltage Vm3=Vres′−(Vdd15/2+Vsig_res_diff/2) is generated at the other end of the resistor R35.

The reference voltage generation circuit 4c further includes an amplifier A32, pMOS transistors Qp34, Qp35, nMOS transistors Qn32, Qn33, and resistors R36, R37. These components correspond to the amplifier A22, pMOS transistors Qp22, Qp23, nMOS transistors Qn21, Qn22, and resistors R22, R23 in FIG. 10, respectively. Therefore, although a detailed description is omitted, a voltage obtained by subtracting the intermediate voltage Vm3 from the power supply voltage Vdd, that is, the reference voltage Vref of the above formula (7), is generated.

As described above, in the third embodiment, the reference voltage Vref is generated according to the power supply voltage Vdd15 of the PGA 6 to perform the common voltage adjustment. Therefore, it is possible to more accurately generate an output voltage corresponding to the signal voltage Vsig.

### Fourth Embodiment

In a fourth embodiment described below, a toleration voltage guarantee circuit is provided.

As shown in FIG. 3, it is estimated that the signal voltage Vsig when the intensity of the light is high is about 1.0 V. However, when the intensity of the light is extremely high, the signal voltage Vsig may fall below 1.0 V and may reach near 0 V.

It is preferable that the pMOS capacitors C1 and C2 shown in FIG. 4 has thin gate oxide film in order to obtain a sufficient capacity while the size is small as much as possible. In this case, when 2.5 V is supplied as the adjustment voltage Vbp and 0 V is supplied as the signal voltage Vsig, the voltage difference is 2.5 V, which may affect the toleration voltage.

Therefore, in the present embodiment, a toleration voltage guarantee circuit 8 is provided to each signal line Vpix(k).

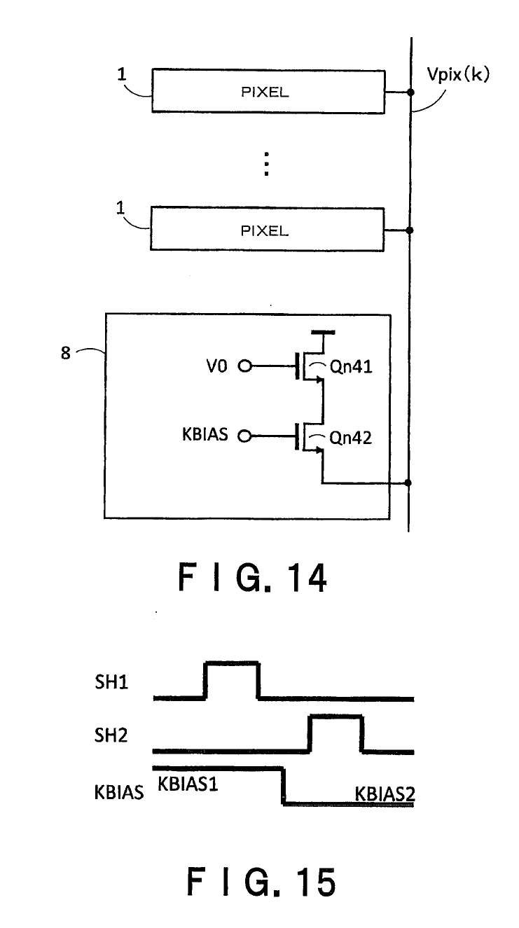

FIG. 14 is a circuit diagram showing an example of the toleration voltage guarantee circuit 8. The toleration voltage guarantee circuit 8 includes nMOS transistors Qn41 and Qn42 connected in series between the power supply terminal and the signal line Vpix(k). Predetermined bias V0 and KBIAS are inputted into the gates of the transistors Qn41 and Qn42, respectively.

The toleration voltage guarantee circuit 8 restricts the voltage value of the signal line Vpix(k) so that the voltage value of the signal line Vpix(k) does not fall below a certain lower limit by a source follower.

FIG. 15 is a schematic timing chart of the bias KBIAS supplied to the toleration voltage guarantee circuit 8. When the signal SH1 is high, that is, when the reset voltage Vres is read, the bias KBIAS is set to a relatively high value KBIAS1. Thereby, the reset voltage Vres becomes approximately 1.5 V. When the signal SH2 is high, the bias KBIAS is set to a relatively low value KBIAS2. Thereby, even when the voltage outputted from the pixel 1 is low, a voltage is supplied from the toleration voltage guarantee circuit 8. Thereby, it is possible to limit the voltage value of the signal line Vpix(k). As a result, it is possible to limit the voltage value of the pMOS capacitor C2.

A specific value of the bias KBIAS may be appropriately adjusted so that the voltage of the signal line Vpix(k) when the reset voltage Vres is read is about 1.5 V and the lower limit of the voltage of the signal line Vpix(k) when the signal voltage Vsig is read is about 1.0 V by a circuit simulation or an experiment.

In this way, in the fourth embodiment, the lower limit of the voltage of the signal line Vpix(k) is restricted by providing the toleration voltage guarantee circuit 8. Thereby, it is possible to protect the pMOS capacitors.

The circuits shown in the drawings are only examples and various modifications can be applied. For example, at least a part of the MOS transistors may be formed by other semiconductor devices such as a bipolar transistor. The conductivity types of the transistors may be reversed and accordingly the connection positions of the power supply terminals and the ground terminals may be reversed. Also in this case, the basic operating principle is the same.

The entire circuit of the image sensor according to the present embodiments may be formed on the same semiconductor substrate or a part of the circuit may be formed on another semiconductor substrate.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fail within the scope and spirit of the inventions.

1. A semiconductor integrated circuit comprising:
a CDS (Correlated Double Sampling) circuit comprising a first capacitor and a second capacitor, the first capacitor comprising a first electrode and a second electrode, the second capacitor comprising a third electrode and a fourth electrode, the CDS circuit being configured to hold a voltage corresponding to light intensity as a signal voltage; and
an adjustment voltage generator configured to supply an adjustment voltage to the CDS circuit,
wherein
a first signal voltage is supplied to the first electrode,
a second signal voltage is supplied to the third electrode, and
the second electrode and the fourth electrode are commonly connected and supplied with the adjustment voltage from the adjustment voltage generator.

2. The circuit of claim 1, wherein the first capacitor and the second capacitor are p-MOS (p-type Metal-Oxide-Semiconductor) capacitors.

3. The circuit of claim 1, wherein
the first signal voltage is a reset signal which is generated by a pixel of an image sensor when light is not irradiated on the image sensor, and
the second signal voltage is a signal voltage which is generated by the pixel when light is irradiated on the image sensor.

4. The circuit of claim 1, wherein
the CDS circuit is connected to an amplification circuit configured to amplify a difference between a voltage of the first electrode and a voltage of the third electrode, and
the adjustment voltage is a voltage for the common voltage of the CDS circuit approaching a common voltage of the amplification circuit.

5. The circuit of claim 3, wherein
the common voltage of the amplification circuit is lower than the common voltage of the CDS circuit, and
the adjustment voltage generator is configured to supply a first voltage to the CDS circuit when the first signal voltage is applied to the first electrode and when the second signal voltage is applied to the third electrode, and thereafter, configured to supply a second voltage to the CDS circuit, the second voltage being lower than the first voltage.

6. The circuit of claim 5, wherein
the adjustment voltage generator comprises:
a replica circuit configured to generate a voltage equivalent to the first signal voltage generated by the pixel,
a reference voltage generation circuit configured to generate the second voltage based on the voltage generated by the replica circuit, and
a voltage selector configured to output either one of the first voltage and the second voltage.

7. The circuit of claim 6, wherein
the common voltage of the CDS circuit before the adjustment depends on the first signal voltage, and
the reference voltage generation circuit is configured to generate the second voltage so that the common voltage of the CDS circuit after the adjustment does not depend on the first signal voltage.

8. The circuit of claim 6, wherein the reference voltage generation circuit is configured to generate the second voltage based on the voltage generated by the replica circuit and a power supply voltage of the amplification circuit.

9. The circuit of claim 8, wherein
the common voltage of the amplifier circuit depends on the power supply voltage of the amplification circuit, and
the reference voltage generation circuit is configured to generate the second voltage so that the common voltage of the CDS circuit after the adjustment approaches the common voltage of the amplification circuit determined according to the power supply voltage of the amplification circuit.

10. The circuit of claim 1, wherein
the CDS circuit is connected to an amplification circuit configured to amplify a difference between a voltage of the first electrode and a voltage of the third electrode, and
the adjustment voltage is a voltage for the common voltage of the CDS circuit approaching ½ of the power supply voltage of the amplification circuit.

11. The circuit of claim 1 further comprising a toleration voltage guarantee circuit configured to limit the voltage of the third electrode to be higher than or equal to a first value.

12. An image sensor comprising:
a pixel;
a CDS (Correlated Double Sampling) circuit comprising a first capacitor and a second capacitor, the first capacitor comprising a first electrode and a second electrode, the second capacitor comprising a third electrode and a fourth electrode, the CDS circuit being configured to hold a voltage corresponding to light intensity irradiated on the pixel as a signal voltage;
an adjustment voltage generator configured to supply an adjustment voltage to the CDS circuit;
an amplification circuit configured to amplify a difference between the first signal voltage and the second signal voltage which are held by the CDS circuit; and
an AD converter configured to convert an output voltage of the amplification circuit into a digital value,
wherein
a first signal voltage is supplied to the first electrode,
a second signal voltage is supplied to the third electrode, and
the second electrode and the fourth electrode are commonly connected and supplied with the adjustment voltage from the adjustment voltage generator.

13. The sensor of claim 12, wherein the first capacitor and the second capacitor are p-MOS (p-type Metal-Oxide-Semiconductor) capacitors.

14. The sensor of claim 12, wherein
the first signal voltage is a reset signal which is generated by the pixel when light is not irradiated on the image sensor, and
the second signal voltage is a signal voltage which is generated by the pixel when light is irradiated on the image sensor.

15. The sensor of claim 12, wherein the CDS circuit is configured to output the reset voltage and the signal voltage to the amplification circuit not via a buffer.

16. The sensor of claim 12, wherein the adjustment voltage is a voltage for the common voltage of the CDS circuit approaching a common voltage of the amplification circuit.

17. The sensor of claim 14, wherein
the common voltage of the amplification circuit is lower than the common voltage of the CDS circuit, and
the adjustment voltage generator is configured to supply a first voltage to the CDS circuit when the first signal voltage is applied to the first electrode and when the second signal voltage is applied to the third electrode, and thereafter, configured to supply a second voltage to the CDS circuit, the second voltage being lower than the first voltage.

18. The sensor of claim 17, wherein
the adjustment voltage generator comprises:
a replica circuit configured to generate a voltage equivalent to the first signal voltage generated by the pixel,
a reference voltage generation circuit configured to generate the second voltage based on the voltage generated by the replica circuit, and
a voltage selector configured to output either one of the first voltage and the second voltage.

19. The sensor of claim 18, wherein
the common voltage of the CDS circuit before the adjustment depends on the first signal voltage, and
the reference voltage generation circuit is configured to generate the second voltage so that the common voltage of the CDS circuit after the adjustment does not depend on the reset voltage.

20. The sensor of claim 18, wherein the reference voltage generation circuit is configured to generate the second voltage based on the voltage generated by the replica circuit and a power supply voltage of the amplification circuit.
